(19) United States
(12) Patent Application Publication
(10) Pub. No.: US 2011/0074422 A1
(43) Pub. Date: Mar. 31, 2011

(54) METHOD AND APPARATUS FOR MAGNETIC RESONANCE IMAGING AND SPECTROSCOPY USING MULTIPLE-MODE COILS

(75) Inventors: Xiaoliang Zhang, Oakland, CA (US); Zhentian Xie, Oakland, CA (US)

(73) Assignee: THE REGENTS OF THE UNIVERSITY OF CALIFORNIA THE OFFICE OF THE PRESIDENT, Oakland, CA (US)

(21) Appl. No.: 12/990,541

(22) PCT Filed: Apr. 29, 2009
(86) PCT No.: PCT/US09/42158

§ 371 Date: Nov. 22, 2010

Related U.S. Application Data
(60) Provisional application No. 61/050,178, filed on May 2, 2008.

(51) Int. Cl. G01R 33/44

(52) U.S. Cl. 324/318

(57) ABSTRACT

A RF coil for use with a resonance imaging device, the RF coil comprises a conductor comprising a first conductive region, a second conductive region substantially isolated from the first portion along its length, and at least one coupling portion adjacent to ends of the first and second portions and configured to electrically couple the first and second portions at a first predetermined frequency. The coil further includes a dielectric substrate supporting the conductor. The RF coil is configured to perform one of excitation, detection, reception, or a combination thereof. A method of using one or more RF coil is further disclosed.

### CROSS-REFERENCE TO RELATED APPLICATIONS

This application claims priority to U.S. Provisional Patent Application Ser. No. 61/050,178 filed May 2, 2008 which is herein incorporated by reference in its entirety for all purposes.

### STATEMENT AS TO RIGHTS TO INVENTIONS MADE UNDER FEDERALLY SPONSORED RESEARCH AND DEVELOPMENT

This invention was made with government support under EB004453, QB3 Opportunity Award awarded by the National Institutes of Health. The government has certain rights in the invention.

### FIELD OF THE INVENTION

This invention relates, in general, to imaging and analysis of targets. This invention also relates to magnetic resonance imaging and nuclear magnetic resonance imaging devices and methods for their use. Various aspects of the invention relate to imaging and analysis for the medical and healthcare fields.

### BACKGROUND OF THE INVENTION

Surface, volume, and hybrid or half coils are commonly used in magnetic resonance imaging (MRI) or spectroscopy procedures in order to obtain accurate and detailed images of tissue under investigation. Coils making use of the same phenomenon are further used to study nuclei and other matter of interest. Such coils are based upon the fact that nuclear magnetic resonance (NMR) phenomenon occurs for each unique nucleus at a unique characteristic frequency, referred to in the art as the Larmor frequency.

Conventional MRI and NMR devices employ coils generally configured to perform several operations. In particular, such coils are used to emit a radio frequency and excite the magnetizations of a target and also to receive or detect a magnetic field produced by the target. Further information regarding general principles of MRI and RF coils may be found in Gary Shen, et al, MRM 38:717-725 (1997); Schnall M D, et al, JMR 65:122-129 (1985); Hayes, et al., JMR 63:622 (1985); and J. Tropp, JMR, 82:51-62 (1989), the contents of which are incorporated in their entirety by reference thereto.

The two most common types of NMR examinations are imaging and spectroscopy. NMR imaging is used to acquire a composite spatial image by repetitively localizing the NMR phenomenon to small picture elements (pixels) within an area of interest. Another separate application of the nuclear magnetic resonance phenomenon is that of NMR spectroscopy. The general field of NMR spectroscopy deals with performing a detailed analysis of the NMR signal in the frequency domain, again for a particular area of interest.

A common problem in NMR and MRI applications involves the need for exciting or receiving signals across a wide range of frequencies in multiple modes. In the context of NMR spectroscopy, it is often necessary to first localize the NMR phenomenon to the area of interest in which the spectroscopy is to be performed. In practice, this localization is performed by first using the NMR apparatus in an imaging mode to acquire an image for verifying the spatial coordinates of the area used for the subsequent spectroscopy. After establishing the correct spatial coordinates through NMR imaging, the NMR apparatus is changed to operate in a spectroscopy mode, and the desired spectrum is acquired.

A similar problem arises in that NMR imaging is typically performed using protons (1H) as the nucleus of interest while the spectroscopy is normally performed on another nucleus having a substantially different Larmor frequency, for example, phosphorous, sodium, fluorine or carbon nuclei.

In high fields (3 Tesla and beyond), due to the high Larmour frequencies required, radiation losses of RF coils become significant which decreases a coil's quality factor or Q factor, and a low Q factor can result in low signal-to-noise ratio (SNR) in MRI procedures. One existing solution to reducing radiation losses is adding RF shielding around the coil(s). The RF shielding, however, usually makes the physical size of RF coil much larger.

Several apparatus have been devised to operate across a wide range of resonant frequencies. Conventional devices may be tuned to operate at the different frequencies required by the application. One such device includes a single coil with a control circuit configured to cause the coil to resonate at low and high frequencies. Such devices are commonly referred to as double-tuned coils because they can be operated at two frequencies. Such devices tend to have limited operating range and are less accurate because conventional coil configurations generally only operate well within a portion of the typical operating spectrum. For example, a conventional coil may perform well in low frequencies, but at higher frequencies noise and signal degradation can be significant.

Another device is constructed of a pair or set of coils connected to a switchable circuit. In a dual frequency coil pair, a first coil is tuned to the Larmor frequency of the nuclei to be used for imaging, while the second coil is tuned to the Larmor frequency of the nuclei to be used for spectroscopy. Thus, circuit drives the first coil in one mode and the second coil in the second mode.

Dual-frequency coil pairs tend to be more complex and costly than single-coil devices. Prior dual frequency coil pairs also exhibit mutual losses induced between the individual coils in the coil pair. Each individual coil in the dual coil pair experiences a degradation of the coil's quality factor, Q, due to loading caused by electromagnetic coupling to the other coil in the dual coil pair even though the other coil is tuned to a different frequency.

Other types of dual frequency coil pairs utilize individual coils in the pair positioned such that the mutual coupling therebetween is minimized by their geometrical relationship to each other. In this case, the mutual degradation of coil Q can be reduced, but a different drawback is introduced in that each coil in the dual frequency coil pair then has a different field of view. The difference in field of view can be approximately compensated for knowing the geometric relation of the individual coils in the dual frequency coil pair; however, such compensation is at best an estimate and leads to less-accurate results.

Due to the aforementioned problems with prior dual frequency coil pairs, conventional dual frequency coil pairs have not gained dramatic acceptance. Instead, the alternate prevailing practice is to use a first single frequency coil for performing the imaging to localize the area of interest. Thereafter, an operator carefully marks the position of the imaging coil, removes the imaging coil, and replaces it with a second single frequency coil tuned to the frequency to be used for the spectroscopy. This procedure is time-consuming, tedious, and expensive. This procedure also introduces factors that involve significant chance for error.

In other applications it can be useful to provide a coil capable of operating at two or more frequencies simultaneously. More recently, double resonant operation has become common as a method of obtaining information from two different nuclei simultaneously, especially as hyperpolarization technology has been more extensively applied to metabolism studies. One of the challenges of designing such dual-tuned coils is limiting electrical and magnetic interferences between high-frequency resonant elements and low-frequency resonant elements in the coils. Although it is possible to use trap circuits to block one resonance, dual-resonance operation can not be performed when using the trap circuit. Furthermore, the trap circuit may degrade the NMR efficiency.

There further exists an ongoing need for a device and method for quadrature excitation and reception that is robust and accurate. A common device is referred to as a birdcage and includes a cylinder-shaped cage with conductor positioned on the inside. An exemplar of such a device is U.S. Pat. No. 7,023,209 to Zhang et al., incorporated herein in its entirety by reference thereto.

Such a birdcage coil is a well-established volume coil which creates homogeneous B1 field and MR images. In order to yield homogenous B1 field distribution, sufficient matching among the resonant elements is necessary. Although coupling the resonant elements together could increase field strength and homogeniety, coupling of such conventional resonant elements in the birdcage leads to significant interference and many of the problems described above.

What is needed is a device and method which overcome the above and other disadvantages. What is needed is a simple and compact coil that can operate at more than one frequency. What is needed is a coil that has approximately the same field of view. What is needed is a coil that produces accurate, verifiable results across a wide range of resonant frequencies. What is needed is a robust and accurate device for quadrature excitation and reception in multiple modes.

### SUMMARY OF THE INVENTION

In summary, one aspect of the present invention is directed to a RF coil for use with a resonance imaging device, the RF coil comprises a conductor comprising a first conductive region, a second conductive region substantially isolated from the first portion along its length, and at least one coupling portion adjacent to ends of the first and second portions and configured to electrically couple the first and second portions at a first predetermined frequency. The coil further includes a dielectric substrate supporting the conductor. The RF coil is configured to perform one of excitation, detection, reception, or a combination thereof.

Another aspect of the invention is directed to a method of using a resonance imaging device comprising providing a RF coil including a conductor including a first portion, a second portion substantially isolated from the first portion along its length, and at least one coupling portion adjacent to ends of the first and second portions and configured to electrically couple the first and second portions in a first mode. The coil further includes a dielectric substrate supporting the conductor. The method further includes positioning a target proximate the RF coil and activating the RF coil to perform at least one of excitation, detection, reception, or a combination thereof.

The coil and method of the present invention have other features and advantages which will be apparent from or are set forth in more detail in the accompanying drawings, which are incorporated in and form a part of this specification, and the following Detailed Description of the Invention, which together serve to explain the principles of the present invention.

### BRIEF DESCRIPTION OF THE DRAWINGS

FIG. 1 is a schematic diagram of a coil circuit in accordance with the present invention.

FIG. 2 is a schematic diagram of the coil of FIG. 1 having a coil with a conductive having two isolated current distributions or portions.

FIG. 3 is a schematic diagram of the coil circuit of FIG. 1 illustrating operation in common mode.

FIG. 4 is a schematic diagram of a coil similar to that of FIG. 1 illustrating conductive regions composed of microstrip transmission lines operating in common mode and differential mode.

FIG. 5 is an enlarged cross-sectional view of the coil of FIG. 4.

FIG. 6 is an enlarged perspective view of a coil similar to that of FIG. 2.

FIG. 7 is a schematic diagram of two coils similar to that of FIG. 1 illustrating adjustment of coupling M by changing the distance between the two.

FIG. 8 is a perspective view of a birdcage coil employing a plurality of the coils of FIG. 1.

FIG. 9 is a schematic diagram of the birdcage coil of FIG. 8.

FIG. 10 is a schematic circuit diagram of the birdcage coil of FIG. 8.

FIGS. 11A-11B are reproductions of 7 T proton images of a kiwi and a cylindrical water phantom acquired using a prototype birdcage coil in accordance with the present invention.

FIGS. 12A-12B are reproductions of 7 T proton images and ¹³C chemical shift imaging of a corn oil phantom acquired using a prototype birdcage coil in accordance with the present invention.

FIG. 13 is a reproduction of simulated homogeneity of B₁ field ratios using an 8-element coil in accordance with the present invention.

FIGS. 14A-14B are reproductions of preliminary results of 7 T proton images and ¹³C chemical shift imaging of a corn oil phantom acquired using a prototype coil in accordance with the present invention.

### DETAILED DESCRIPTION OF THE INVENTION AND THE PREFERRED EMBODIMENTS

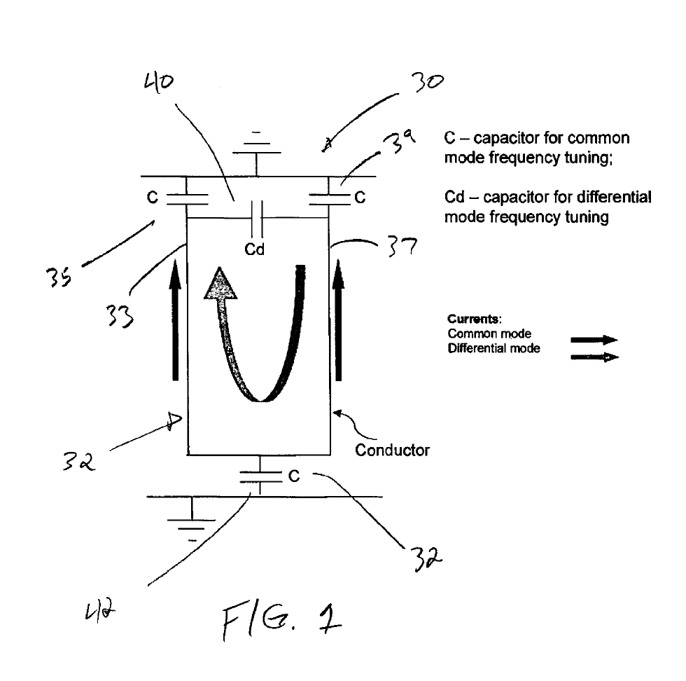

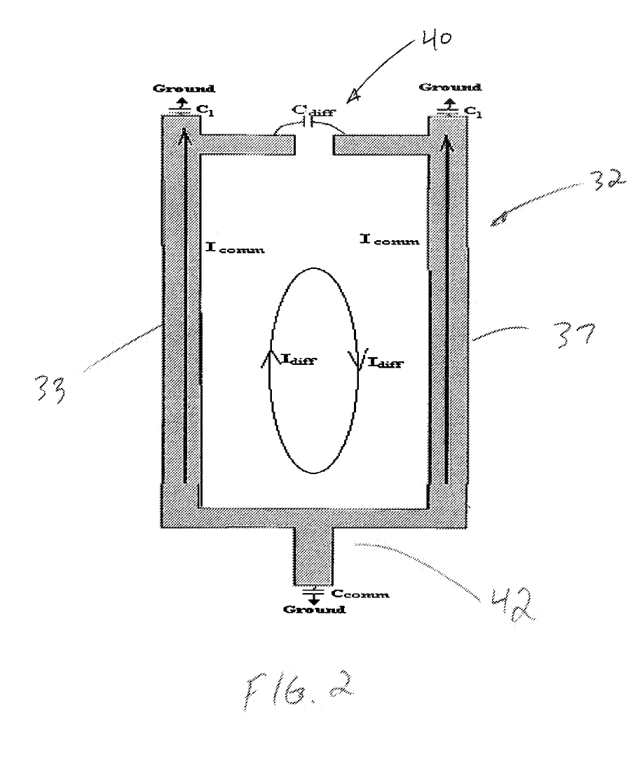

Reference will now be made in detail to the preferred embodiments of the invention, examples of which are illustrated in the accompanying drawings. While the invention will be described in conjunction with the preferred embodiments, it will be understood that they are not intended to limit the invention to those embodiments. On the contrary, the invention is intended to cover alternatives, modifications and equivalents, which may be included within the spirit and scope of the invention as defined by the appended claims. Turning now to the drawings, wherein like components are designated by like reference numerals throughout the various figures, attention is directed to FIGS. 1-3.

Hyperpolarized ¹³C with high field MR spectroscopy and spectroscopic imaging techniques proves to be promising for metabolism studies in vivo. A coil, generally designated 30, is configured for use with a resonance imaging device such as a MRI machine or NMR spectroscopy device (not shown).

Coil 30 includes a conductor, generally designated 32, for conducting a current and transmitting a radio frequency (RF) pulse or creating a magnetic field or for receiving an electrical or magnetic signal. Suitable materials for the conductor include, but are not limited to, conductive metals such as copper or silver. In various embodiments, the conductor material is non-magnetic.

Conductor 32 includes a first conductive portion or region 33 terminating at a first capacitive end 35 and a second conductive region 37 terminating at a second capacitive end 39. The conductive portions are each configured to conduct an electrical current and to perform one or more of transmitting a RF signal, receiving a RF signal, transmitting magnetic flux lines, and receiving or detecting magnetic flux lines.

The second portion is isolated from the first portion along its length. As used herein, “isolation” refers to a structure or configuration that significantly reduces interference with one member by another member in operation. For example, although some leakage may be expected, isolation may refer to reduction interference of one portion with the other portion such that the affects of one is negligible as would be understood by one skilled in the art.

Isolation may be provided by physical structures such as shields configured to absorb electromagnetic flux or force lines. In various embodiments, the second portion substantially parallels the first portion and the physical distance between the two portions provides isolation such that the use of filters, shields, and other techniques are not necessary to obtain results of desired accuracy. The second portion may also be oriented such that the magnetic field of the second portion is substantially orthogonal to the first portion thereby isolating the second portion from the first portion and vice versa.

Conductor 32 may further include a coupling portion or region 40 proximate the capacitive ends of the first and second conductive regions. The coupling portion is configured to couple the first portion and the second portion for tuning the resonance of the first and second portions. In various embodiments, the coupling portion is composed of a conductive line and capacitor configured to allow current flow therethrough during a desired mode of operation. As will be described below, current may flow through the coupling portion in one mode but not in another mode such that the first and second portions are electrically coupled only in one mode.

The conductor includes a capacitive termination end 42 coupling the first portion to the second portion at opposite ends of coupling portion 40. Thus, the coil is connected at each end to a ground. At one end first portion 33 and second portion 37 are coupled directly to each other by termination end 42, which is fed to the ground. At an opposite end, the first portion and second portion are coupled together by coupling portion 40 configured to control the coupling of the two portions thereby allowing coil tuning.

In various embodiments, the first and second portion are physically separated from each other and the coupling portions—coupling portion 40 and termination end 42—form ends of a loop. Accordingly, as will be described below, in one mode, current may flow in a loop. In another mode, such as common mode, the current will flow from end 42 separately through the first and second portions and to the ground. In differential mode, the looping effect provides for mutual inductance between the first and second portions. Thus, high differential mode inductance can be achieved with a single coil.

In various embodiments, conductor 32 is positioned in whole or in part on a support 44 such as a dielectric substrate. The entire conductor may be positioned on a single, monolithically formed substrate material. The substrate material may be formed of a dielectric material or may be formed as a dielectric through the use of a dielectric layer or like configuration.

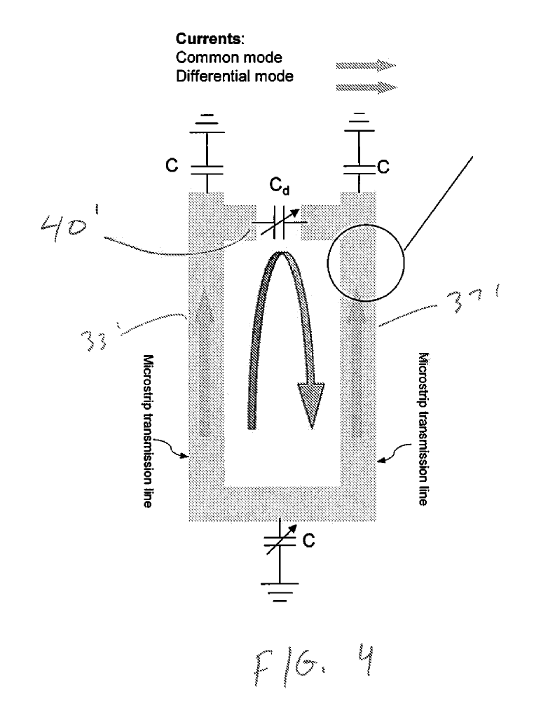

In various embodiments, the conductor is composed of microstrip transmission line (MTL). Referring to FIGS. 4-6, one or more of the coupling portions and first and second conductive portions may be formed of a strip conductor 32′, a ground plane 46 and a dielectric material 44′. The dielectric material may be air, a vacuum, low loss dielectric sheets such as Teflon or Duroid, liquid Helium or liquid Nitrogen, or the like. In various embodiments, the strip conductor or ground plane are formed in whole or in part from a non-magnetic, conductive material such as copper.

In various embodiments, the conductor is configured such that the coil is magnetically driven when coupling portion 40 couples the first and second portions and a loop circuit is created. Likewise, the conductor may be configured to be electrically driven when the first and second portions are not coupled by coupling portion 40, in which case electrical current flows through the first coupling portion—the capacitive termination end—into each conductive portion and to the ground.

In various embodiments, one end of the conductor is connected to a proton port and another end is connected to a carbon port. In various embodiments, one of the coupling portions is connected to a proton port and another coupling portion is connected to a carbon port. In various embodiments, one coupling portion is connected to a high frequency port and another coupling portion is connected to a low frequency port.

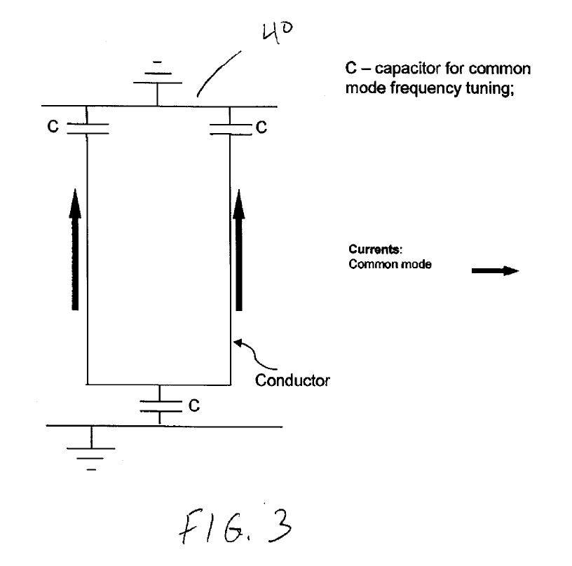

Referring generally to FIGS. 1-6, the conductor may be configured to operate in common mode or differential mode at different times or simultaneously. Coil 30′ allows for common mode and differential mode (CMDM) to exist within two coupled regions—first portion and second portion. This structure yields two current distributions and magnetic radiation fields. FIGS. 1-4, and in particular FIG. 3, show that in the common mode, the two currents on a resonator are identical. In the differential mode, the currents are opposite to form a current loop on resonator coil 30′.

Both currents and magnetic fields in the CMDM coil are thus isolated between the two modes. Therefore, these modes can be designed independently at two resonant frequencies without any interference therebetween.

In operation and use, the quadrature is configured to operate in common mode and differential mode without changing the coil elements. In various embodiments, coil is connected to a proton port and non-proton port, a carbon port for example. In the proton channel, each of the eight coils is configured as common mode resonators with capacitive termination on both ends. Two quadrature proton ports are driven electrically. The carbon channel includes eight coils. In order to operate at the relatively low frequency of 75 MHz, the coils operate at differential mode to form loop currents. One end including coupling 42 is capacitively terminated, and the other end of the coil including coupling portion 40 is shorted to ground. Two quadrature proton ports are driven inductively. The configuration of the conductor, coil, and structure employing multiple coils may be modified depending on the application as would be understood by one skilled in the art from the foregoing description.

Turning now to operation and use, a structure including a coil 30 as described above is provided. A target (not shown) is positioned in a target region defined by the structure. Thereafter, the coil is activated to perform at least one of excitation, detection, reception, or a combination thereof. The coil may be activated to generate a magnetic resonance signal from the first and second conductor portions, or the coil may be activated such that a signal is received by the first and second portions. The coil may also be configured to excite the magnetizations of a target.

As described above, the coil, whether formed as a surface coil, volume coil, or hybrid, may operate in at least two modes one-at-a-time or simultaneously. The coil may be configured to operate in a first differential mode and the second common mode. In various embodiments, the target is ¹H in one mode and at least one of phosphorous, sodium, fluorine or carbon nuclei in a second mode.

As will be understood from the foregoing, the above structure thus provides two conductive portions isolated from each other to reduce magnetic and electrical interference while still allowing operation in common mode and differential mode.

The coil in accordance with the present invention provides several advantages over conventional coils. The coil allows for multiple tuning designs and effective operation with a single coil. The coil may be configured with multiple structures including, but not limited to, microstrips and non-microstrip. A plurality of coils may be used to construct a volume coil, surface coil, or hybrid such as a half-dome coil.

### Example 1

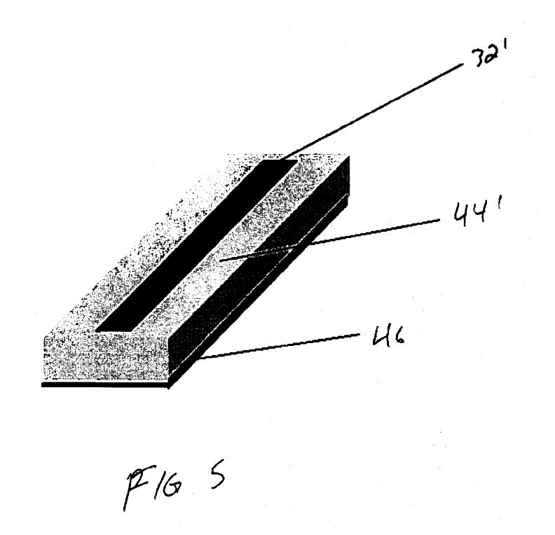

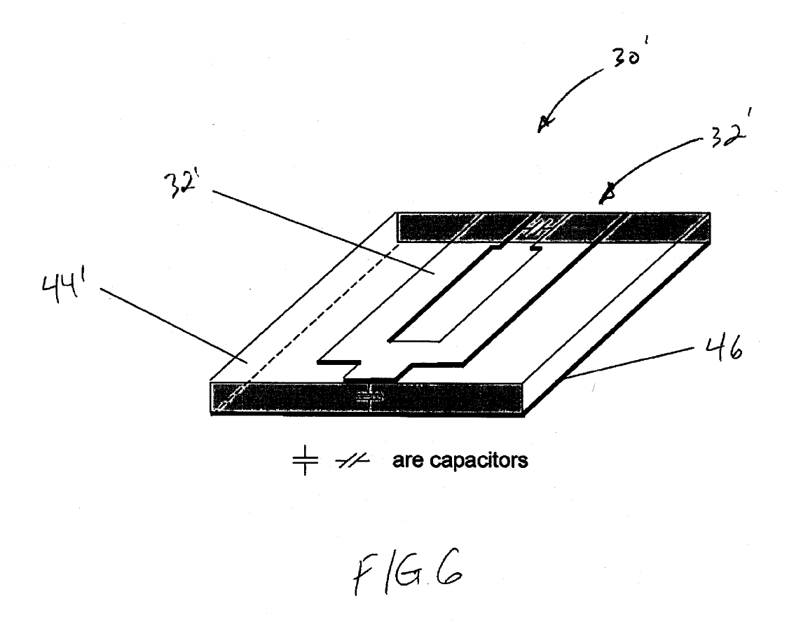

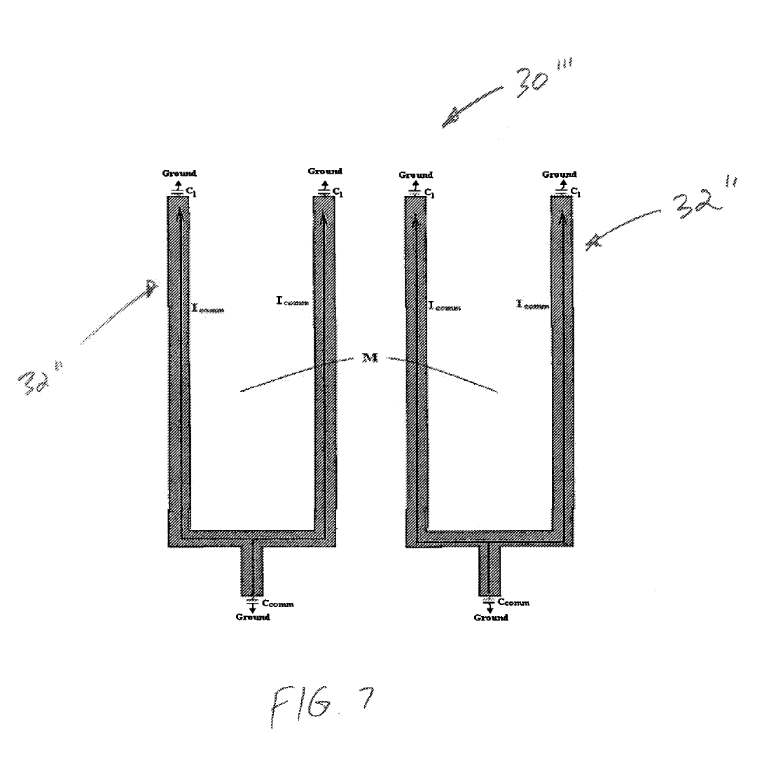

With references to FIGS. 4-7 and 14A-14B, a common mode dual mode carbon-proton microstrip coil 30 working on a 7 T MR system was provided. The coil was configured as microstrip transmission lines similar to the structure shown in FIGS. 5-6. The coil includes eight conductor elements 32 (as shown, e.g., in FIG. 7) configured to operate at 75 MHz and eight conductor elements configured to operate at 298.14 MHz for in vivo ¹³C/¹H MRI/S studies at 7 T. The microstrips are mounted parallel to each other on a 0.64 cm thick acrylic board. The strip conductors are made from back-adhesive copper foils and measure 0.64 cm in width and 9.0 cm in length.

The two microstrips are separated by 1.9 cm and connected directly at one end and connected via a capacitor at an opposite end. The coil is configured as described above such that the parallel microstrips form the common-mode and the loop circuit forms the differential-mode. In the common-mode circuit, which is tuned for proton, each of the two resonant elements is a λ/2 microstrip resonator with capacitive termination at both ends. The common-mode is driven by capacitance while the differential-mode is driven inductance.

Bench tests of the exemplary coil structure were implemented on an Agilent E5070B network analyzer to test coil resonant modes and isolation. The termination capacitance measurement was conducted on a Fluke PM6303A RCL meter. The exemplary coil was also analyzed numerically in terms of the resonance frequency, field distribution, and isolation between the two modes by using an FDTD algorithm. The proton MR imaging and ¹³C spectroscopy experiments were performed on a GE 7 T whole body MR system (sold by GE Healthcare, Waukesha, Wis.).

Preliminary results on proton imaging and ¹³C MRSI from a corn oil phantom were also demonstrated using the exemplary CMDM coil 30 at 7 T. A set of spin echo images in axial images was collected with TR=2 seconds, 9 mm in-plane and 20 mm thick, number of excitation (NEX)=1.

The dual-tuned transceiver coil was tuned to 298.14 MHz (for ¹H) and 75 MHz (¹³C) on the two driven ports, respectively. Each port was matched to system 50 Ohm by a series capacitor. Well-matched resonance peak for the ¹H channel and ¹³C channel were identified on the network analyzer. The isolation between driving ports was shown to be greater than 30 dB between the ¹H channel and ¹³C channel in both loaded and unloaded cases. FDTD analysis showed better than a −46 dB decoupling or isolation between the two channels.

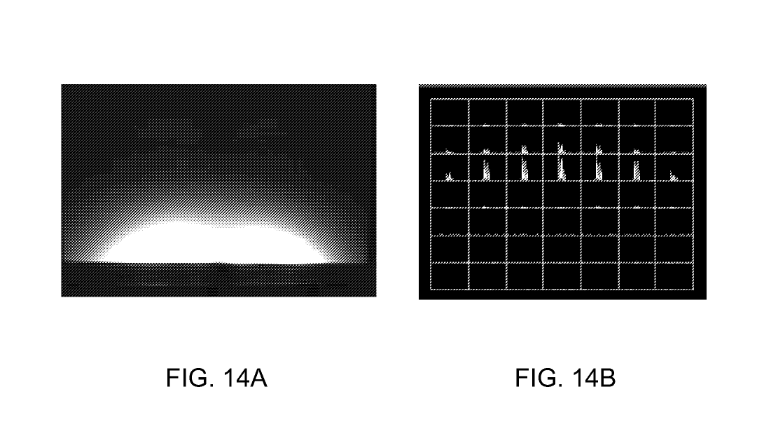

FIGS. 14A-14B illustrate a proton spin echo image and ¹³C spectroscopic imaging. FIG. 14A illustrates a 7 T proton image. FIG. 14B illustrates ¹³C chemical shift imaging of the corn oil phantom acquired using the exemplary CMDM transceiver coil at 7 T. The B₁ fields of ¹H channel (common mode) and ¹³C channel (differential mode) have a similar distribution.

One of the demonstrated advantages of the exemplary structure is that the two magnetic fields have a similar distribution which helps B₀ shimming for low-gamma nuclei, which was confirmed by the FDTD simulation results and real MR imaging. The coils and resonators in accordance with the present invention provide a simple and efficient approach to MR and NMR including the design of dual-tuned surface coils for in vivo multi-nuclear MR at ultrahigh fields. The dual-tuned resonator can also be used as resonant elements of parallel imaging arrays for multi-nuclear MR applications in accordance with the present invention.

### Example 2

Referring to FIGS. 5-6, a dual-tuned carbon-proton volume coil working on an exemplary 7 T MR system is provided. The volume coil includes eight conductor elements 32′ configured to operate at 75 MHz and eight conductor elements configured to operate at 298.14 MHz for in vivo ¹³C/¹H MRI/S studies at 7 T.

The single element CM coil 30′ can be used for MR imaging. It also can also be used to form volume coils for homogeneous imaging with increased image coverage (either microstrip or non-microstrip). The coil and conductor may be modified in other manner as will be understood from the foregoing depending on the application.

### Example 3

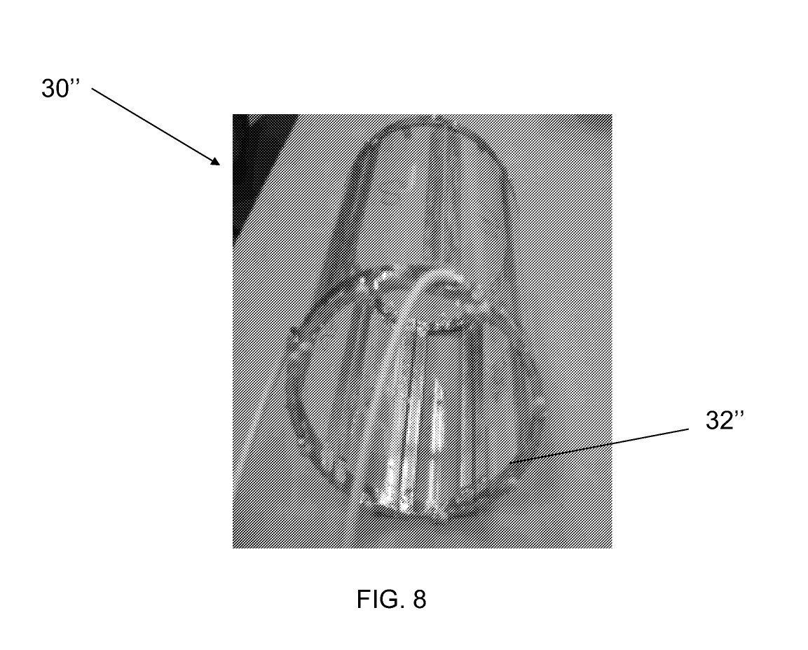

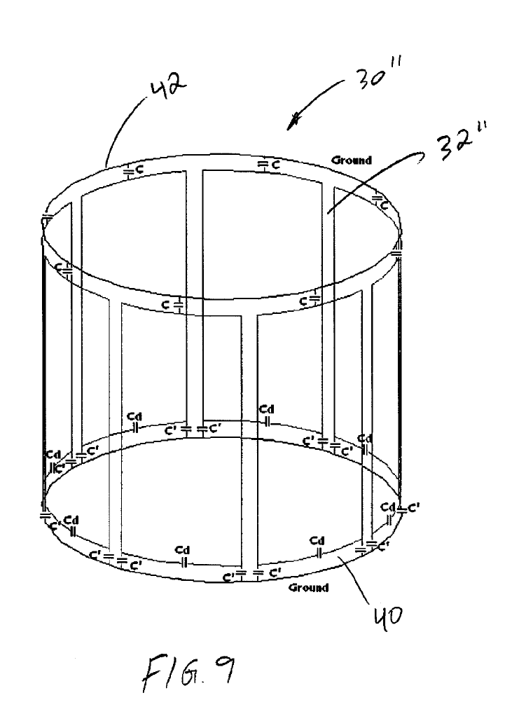

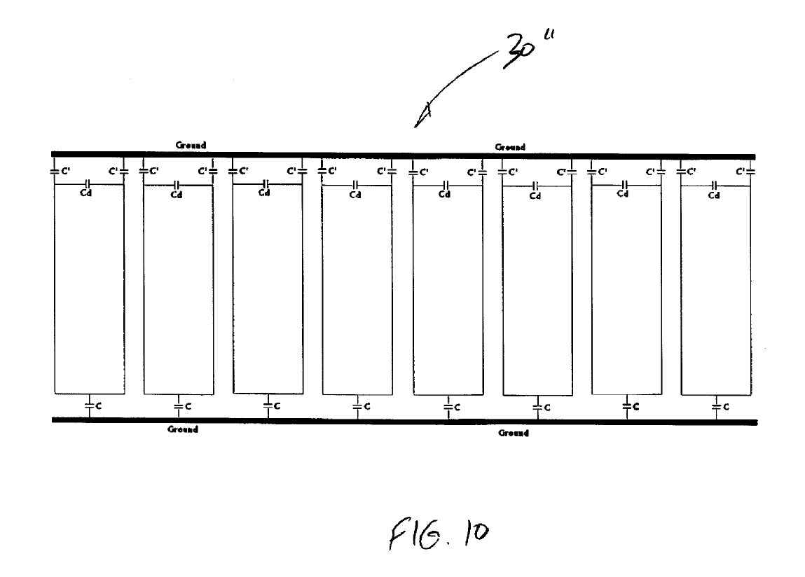

Referring to FIGS. 7-12, a quadrature structure 47 is provided employing one or more coils 30″ similar to coil 30 and coil 30′. The structure is dual-tuned. The structure may be a single tuned quadrature volume coil array when the two modes are tuned to the same frequency and all the elements are decoupled.

In the exemplary embodiment, the structure is a 7 T CM birdcage coil with eight coil elements for ¹H imaging. The gap between each of the coils is 1/16″. The quadrature CMDM dual-tuned volume coil is built on a cylindrical substrate composed of acrylic with dimensions of 4″ O.D, 3.75″ I.D and 4″ in length. The acrylic cylinder serves as both a dielectric material and mechanical support. Each of the CMDM coil elements have a 0.0625″ gap between them.

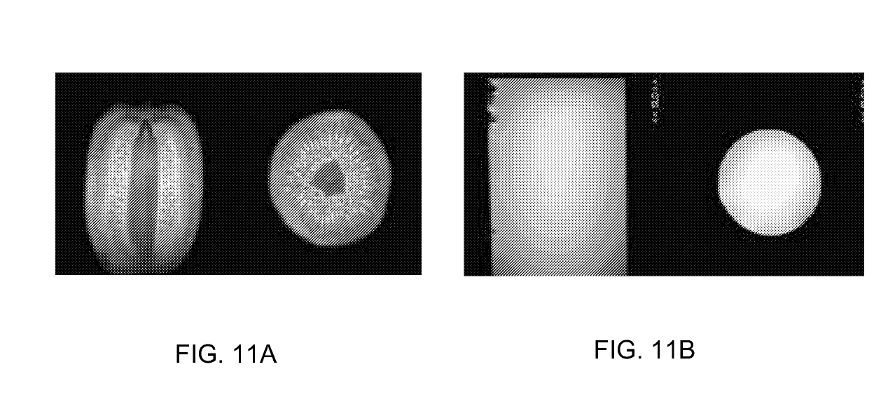

FIG. 11 illustrates the results of bench tests for a structure manufactured in accordance with the above. To simulate the effects of the adjustable distance between the CM elements for B₁ homogeneity and coil sensitivity, the magnetic field of the 8-coil element CM birdcage coil with different gaps were simulated by using Biot-Savart law.

The proton channel and carbon channel were tuned to 298.14 MHz and 75 MHz on the two quadrature ports respectively. Each port was matched to system 50 Ohm by a series capacitor. Well-defined five resonance peaks for ¹H channel and five peaks for ¹³C channel are clearly identified on the network analyzer. On the bench test, the isolation between driving ports was greater than 20 dB for both ¹H channel and ¹³C channel. These results indicate that the two channels of ¹H and ¹³C are decoupled sufficiently.

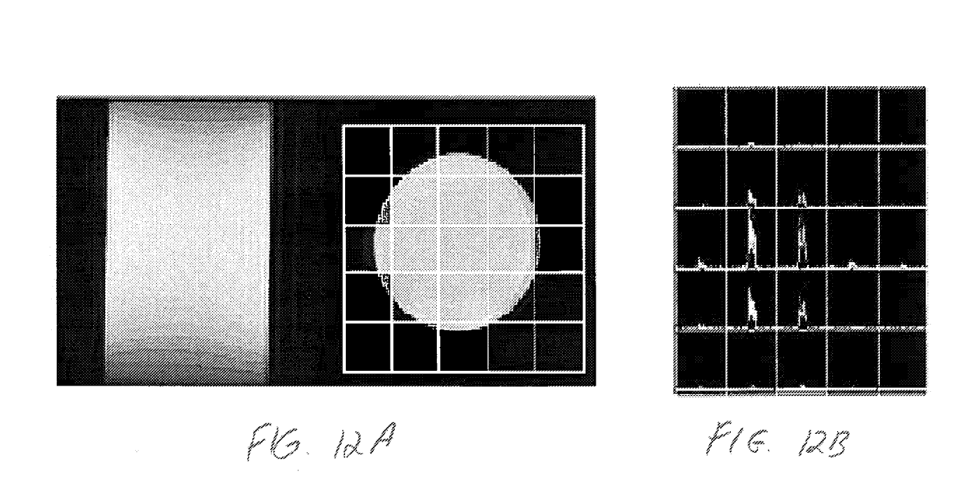

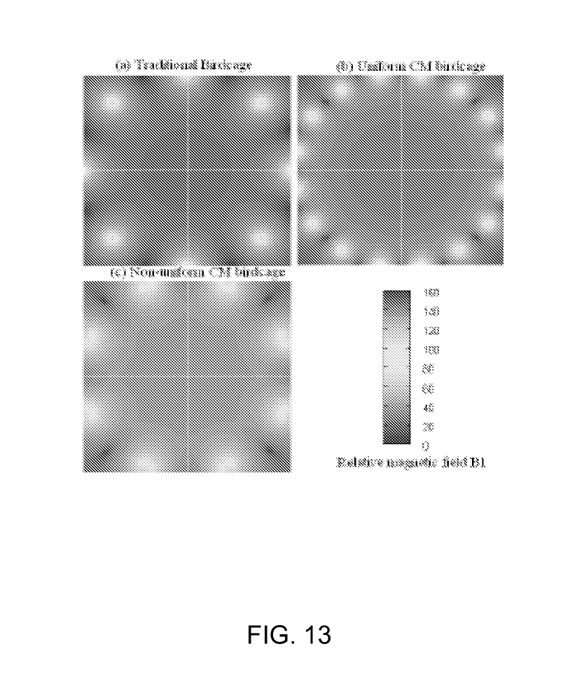

A proton GRE image and ¹³C CSI using the same testing equipment described in Example 1 are shown in FIGS. 12-13. The results confirm that the proposed design may provide a simple and efficient approach to dual-tuned volume coil design for in vivo multinuclear MR at ultrahigh fields.

A simulated homogeneity of B₁ field (the ratio to the magnetic field of the coil isocenter) for the coil is shown in FIG. 13. FIG. 13A illustrates the B₁ field with a traditional 8-element birdcage having a ½″ gap. FIG. 13B illustrates the relative B₁ field with an 8-element uniform CM volume coil having a ¼″ gap and uniform distributed legs or strips. FIG. 13C illustrates the relative B1 field with a 8-element CM volume coil having a 1/16″ gap. The computed area of the coil is 3.75″ in-plane.

The homogeneity of B₁ field was improved when decreasing the gaps between the CM coils, as shown for example in the structure of FIG. 7. The sensitivity of the coil is within acceptable levels. The proton channel was tuned to 298.14 MHz. Each port was matched to system 50 Ohm by a series capacitor. Well-defined five resonance peaks for ¹H channel are clearly identified on the network analyzer. These results indicate that the ¹H elements were sufficiently coupled and yield homogenous B₁ distributions without increasing element numbers.

The proposed design thus provides a simple and easy-to-implement approach to generate homogeneous B1 field in birdcage volume coil for MR at ultrahigh fields. In various embodiments, when coil is tuned to the same frequency, the coil mimics a conventional quadrature coil which can significantly increase MR signal-to-noise ratio (SNR) and significantly reduce the required excitation.

In many respects the modifications of the various figures resemble those of preceding modifications and the same reference numerals followed by apostrophes designate corresponding parts.

The foregoing descriptions of various embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the Claims appended hereto and their equivalents.

What is claimed is:

1. A RF coil for use with a resonance imaging device, said RF coil comprising:
a conductor comprising:
a first conductive region;
a second conductive region substantially isolated from the first portion along its length; and
at least one coupling portion adjacent to ends of the first and second portions and configured to electrically couple the first and second portions at a first predetermined frequency; and
a dielectric substrate supporting the conductor,
wherein the RF coil is configured to perform one of excitation, detection, reception, or a combination thereof.

2. A RF coil according to claim 1, wherein the conductor further comprises coupling portions at each end, a first coupling portion forming a capacitive termination and another coupling portion connected to the ground.

3. A RF coil according to claim 2, wherein the first portion and second portion are substantially parallel and the coupling portions forms ends of a loop.

4. A RF coil according to claim 2, wherein a first coupling portion is configured to be magnetically driven and another coupling portion is configured to be electrically driven.

5. A RF coil according to claim 2, wherein one coupling portion is connected to a proton port and another coupling portion is connected to a carbon port.

6. A RF coil according to claim 2, wherein one coupling portion is connected to a high frequency port and another coupling portion is connected to a low frequency port.

7. A RF coil according to of claim 1, wherein the conductor is a microstrip.

8. A RF coil according to claim 1, wherein the second portion is oriented such that the magnetic field of the second portion is substantially orthogonal to the first portion.

9. A RF coil according to claim 1, wherein the conductor is formed on a single substrate.

10. A RF coil according to claim 1, wherein the conductor is monolithically formed.

11. A RF coil according to claim 1, wherein current flows in a loop in a first mode and current flows to the ground in a second mode.

12. A magnetic resonance imaging device comprising:
a substrate configured to define a target region;
one or more RF coils according to any one of the preceding claims, the one or more RF coils disposed on the substrate proximate the target region.

13. Method of using a resonance imaging device comprising:
providing a RF coil comprising:
a conductor comprising:
a first portion;
a second portion substantially isolated from the first portion along its length; and
at least one coupling portion adjacent to ends of the first and second portions and configured to electrically couple the first and second portions in a first mode; and
a dielectric substrate supporting the conductor;
positioning a target proximate the RF coil;
activating the RF coil to perform at least one of excitation, detection, reception, or a combination thereof.

14. A method according to claim 13, wherein the activating is accomplished by generating a magnetic resonance signal from the conductor.

15. A method according to claim 14, wherein the RF coil excites the magnetizations of the target.

16. A RF coil for use with a resonance imaging device, said RF coil comprising:
a conductor comprising:
a first portion terminating at a first capacitive end;
a second portion terminating at a second capacitive end, the second portion substantially parallel to and isolated from the first portion along its length;
a coupling portion proximate the capacitive ends configured to couple the first portion and the second portion for tuning resonance of the first and second portions;
a capacitive termination end coupling the first portion to the second portion at opposite ends of the coupling portion; and
a dielectric substrate supporting the conductor,
wherein the coupling portion is configured to allow current to pass through when the conductor is operating in a first mode and does not allow current to pass through when the conductor is operating in a second mode.

17. A method according to claim 16 wherein RF coil is configured to perform one of excitation, detection, reception, or a combination thereof.

18. A method according to claim 16, wherein the first mode is differential mode and the second mode is common mode.
